(19) United States
(12) Patent Application Publication
(10) Pub. No.: US 2013/0214804 A1
(43) Pub. Date: Aug. 22, 2013

(54) CURRENT SENSOR

(71) Applicants: Timo Dietz, Hochheim (DE); Wolfgang Jöckel, Gersfeld (DE); Klaus Rink, Rodenbach (DE); Thomas Gaertner, Berlin (DE); Helge Grasshoff, Regensburg (DE)

(72) Inventors: Timo Dietz, Hochheim (DE); Wolfgang Jöckel, Gersfeld (DE); Klaus Rink, Rodenbach (DE); Thomas Gaertner, Berlin (DE); Helge Grasshoff, Regensburg (DE)

(73) Assignee: CONTINENTAL TEVES AG & CO. OHG, Frankfurt (DE)

(21) Appl. No.: 13/805,723

(22) PCT Filed: Jul. 1, 2011
(86) PCT No.: PCT/EP2011/061141

§ 371 Date: Feb. 27, 2013

(30) Foreign Application Priority Data
Jul. 1, 2010 (DE) 10 2010 030 805.6
Mar. 29, 2011 (DE) 10 2011 006 377.3

(51) Int. Cl. G01R 27/08

(52) U.S. Cl. CPC G01R 27/08
USPC 324/713

(57) ABSTRACT

The invention relates to a current sensor including at least one resistance element on which voltage (U_{GS}) for measuring the current (i_{MEAS}) flowing through the resistance element is detected. The resistance element is designed so that at least, within a defined measurement range of the current sensor, the electric resistance of the resistance element reduces when the current (i_{MEAS}) flowing through the resistance element increases.

### CROSS REFERENCE TO RELATED APPLICATIONS

This application is the U.S. National Phase Application of PCT/EP2011/061141, filed Jul. 1, 2011, which claims priority to German Patent Application Nos. 10 2010 030 805.6, filed Jul. 1, 2010 and 10 2011 006 377.3, filed Mar. 29, 2011, the contents of such applications being incorporated by reference herein.

### FIELD OF THE INVENTION

The invention relates to a current sensor, comprising at least one resistance element, to which a voltage (U_{GS}) for measuring the current H_{Meas} flowing through the resistance element is detected, and to the use of the current sensor in motor vehicles.

### BACKGROUND OF THE INVENTION

In motor vehicles, current measurements are nowadays carried out at many points. These current measurements are incorporated into closed-loop control circuits, for example, serve for monitoring limit values that or are used for measuring the discharge and/or charging current of a battery. In the latter area of use, the charge state of the battery is determined, inter alia. Moreover, conclusions about the state of the battery are drawn by means of monitoring the internal resistance of the battery. These include the age and the capacity of the battery.

Owing to the search for new drive concepts using renewable energies, numerous developments are concentrating on electric and hybrid drives. The detection of the charge state and of the overall state of the battery is further gaining in importance here. In this case, the current and the voltage of the battery have to be measured. The battery voltages here are up to 1000V and the discharge currents are up to 600 A. The dynamic range of the currents to be measured extends for example from 10 mA to 1000 A, that is to say a factor of 1*10⁻⁵. The accuracy is often intended to be <1% relative to the respective measured value. In order that an excessively high power loss does not arise, the value of the shunt resistance is limited to a maximum of 100 μΩ.

The most widely used current measurement is that on the basis of measuring the voltage across an ohmic resistor (shunt) connected into the electric circuit. In this case, however, it is often difficult to cover the required dynamic range with the required accuracy. By way of example, in the case of a current of 10 mA at the 100 μΩ resistor a voltage of 1 μV is dropped, which has to be measured accurately to 1%. In the case of 1000 A, 100 mV is dropped, which likewise has to be measured very accurately. That firstly requires high-resolution, accurate AD converters; secondly, problems regarding EMC strength can arise on account of the very low voltages and the interference-intensive automotive environment. That drives up the costs.

### SUMMARY OF THE INVENTION

The invention is based on a current sensor which can be used relatively cost-effectively, in particular in the case of a relatively large measurement range or in the case of a relatively large dynamic range of the current to be measured.

This is achieved according to the invention by means of the current sensor comprising at least one resistance element, to which a voltage (U_{GS}) for measuring the current (I_{Meas}) flowing through the resistance element is detected, wherein the resistance element is designed such that, at least within a defined measurement range of the current sensor, the electrical resistance of the resistance element decreases if the current (i_{Meas}) through the resistance element increases.

The invention is based on the concept, in particular, that the resistance element is designed such that, at least within a defined measurement range of the current sensor, the electrical resistance of the resistance element decreases if the current through the resistance element increases, and/or that the electrical resistance of the resistance element increases if the current through the resistance element decreases.

Preferably, the design of the current sensor is based on the requirement that the required resolution of deltal/deltaBit—apart from a proportionality factor—is less than the maximum measurement error e. In this case, deltal is the change in the current to be measured through the at least one resistance element and deltaBit is the measurement resolution quantum defined by an analog-to-digital converter connected downstream. In this case, the maximum measurement error e is intended to be constant or at any time at most p % of the respective measured value, for example they remain below 1%. By way of example, a desired or ideal relationship between measurement voltage and measurement current is derived theoretically from these requirements on the basis of the following equations:

$$required resolution \text{:} \frac{Δ I}{Δ D} = p \% \cdot I = p \% \cdot {I}_{max} \cdot \frac{D}{{2}^{n} - 1} ⇒ ( 1 ) \text{:} Δ I = p \% \cdot {I}_{max} \cdot \frac{D}{{2}^{n} - 1} Δ D \\ ( 2 ) \text{:} \frac{D}{( {2}^{n} - 1 )} = \frac{{U}_{AD}}{{U}_{AD max}} ; ( 3 ) \text{:} Δ D = \frac{{U}_{AD}}{{U}_{AD max}} \cdot ( {2}^{n} - 1 )$$

$$( 2 ) , ( 3 ) \to ( 1 ) ⇒ ( 4 ) \text{:} Δ I = p \% \cdot {I}_{max} \cdot \frac{{U}_{AD}}{{U}_{AD max}^{2}} \cdot ( {2}^{n} - 1 ) \cdot Δ {U}_{AD} \\ ( 4 ) {\to }^{Δ > \partial } ( 5 ) \text{:} \partial I = p \% \cdot {I}_{max} \cdot \frac{{U}_{AD}}{{U}_{AD max}^{2}} \cdot ( {2}^{n} - 1 ) \partial {U}_{AD} \\ ( 6 ) \text{:} I = p \% \cdot \frac{{I}_{max}}{{U}_{AD max}^{2}} \cdot ( {2}^{n} - 1 ) {\int }_{0}^{{U}_{sense}} {U}_{AD} \partial {U}_{AD} \\ ( 7 ) \text{:} I = p \% \cdot \frac{{I}_{max}}{{U}_{AD max}^{2}} \cdot \frac{{2}^{n} - 1}{2} \cdot {U}_{sense}^{2} = p \% \cdot k \cdot {U}_{sense}^{2} \\ ( 8 ) \text{:} {U}_{sense} = \sqrt{\frac{I}{p \% \cdot k}}$$

where:
Iₘₐₓ: maximum measurement current
N: bit width of AD converter
D: AD converted measured value [LSB]
U_{AD}: AD converter input voltage
U_{ADmax} maximum AD conversion range
Uₛₑₙₛₑ: present measurement voltage

The expedient requirement of a percentage-constant resolution ideally gives rise to an at least quadratic relationship between measurement voltage and current to be measured, which can preferably also be approximated by an antiproportional function or a 1/x function between measurement voltage and measurement current, by means of a corresponding design of the resistance element.

The current sensor is preferably designed such that the percentage resolution of the current measurement relative to the present value of the current or the present measurement current through the resistance element remains substantially constant at least over the defined measurement range of the current sensor.

The current sensor preferably comprises at least one closed-loop control circuit which is used to adjust the voltage across the resistance element to a defined reference voltage value, at least within a defined measurement range. In particular, in this case the defined reference voltage value is at least 1 mV, particularly preferably at least 100 mV.

Such a preferred reference voltage value has significantly higher interference immunity in comparison with the voltage value across a shunt in the case of low currents, since the voltage across a shunt usually only has a value in the μV range.

Preferably, the current sensor is designed such that the defined reference voltage is adjustable for extending the measurement range.

The current sensor expediently has at least one reference voltage source in order to provide the at least one reference voltage.

The resistance element preferably comprises at least one transistor element, in particular at least one field effect transistor, particularly preferably at least one MOSFET. For measuring the current flowing through the resistance element, the gate-source voltage or base-emitter voltage at the transistor element is expediently detected.

The defined measurement range of the measurement current preferably comprises at least four powers of ten, in particular at least five powers of ten.

With voltage across the resistance element controlled by closed-loop control, the resistance value of the resistance element is preferably substantially dependent on 1 divided by the value of the current through the resistance element or is substantially dependent on 1 divided by the root of the value of the current through the resistance element.

The at least one resistance element preferably comprises two or more parallel-connected partial resistance elements which are designed such that they can be switched in and/or out, for extending the measurement range, wherein said partial resistance elements are integrated, in particular, into the closed-loop control circuit.

It is preferred for the current sensor to have at least one temperature measuring element which detects the temperature of the at least one resistance element, wherein said temperature is taken into account during the measurement of the current flowing through the at least one resistance element, in particular by a calculation in at least one signal processing unit of the current sensor.

It is expedient for the current sensor to comprise a first and a second closed-loop control circuit, which are used in each case to adjust the voltage across a resistance element to a defined reference voltage value, at least within a defined measurement range, wherein the current to be measured can flow with a first defined direction through the resistance element of the first closed-loop control circuit and the current to be measured can flow with a second direction, opposite to the first direction, through the resistance element of the second closed-loop control circuit, and the current to be measured is detected and measured by means of the first closed-loop control circuit or by means of the second closed-loop control circuit, depending on the current direction. The reference voltage values of the first and second closed-loop control circuits are adjustable differently in particular.

It is preferred for the resistance elements of the first and second closed-loop control circuits to be designed as two field effect transistors designed complementarily to one another, and/or for the resistance elements of the first and second closed-loop control circuits to be connected in parallel and in this case the drain terminal or collector terminal of one resistance element is respectively connected to the source terminal or emitter terminal of the other resistance element, in particular reciprocally.

The at least one resistance element is preferably assigned at least one senseFET connected to an analog-to-digital converter, wherein the current through the resistance element is determined by means of the senseFET.

At least the senseFET and the assigned resistance element are expediently formed jointly on a chip.

Particularly preferably the gate-source voltage or base-emitter voltage of the senseFET is fashioned to be identical to the gate-source voltage or base-emitter voltage of the assigned resistance element.

Expediently, the quotient of the value of the drain-source resistance or collector-emitter resistance of the senseFET with respect to the value of the drain-source resistance or collector-emitter resistance of the assigned resistance element has a defined value. In particular, a reference voltage source or reference current source is connected to the senseFET, as a result of which the temperature influence on the current measurement can be substantially suppressed.

A resolution is preferably understood to mean a defined minimum measurement accuracy.

Expediently, the at least one closed-loop control circuit comprises at least one amplifier as actuator.

The at least one resistance element is preferably embodied as the controlled system of its closed-loop control circuit, wherein in particular the drain-source voltage or collector-emitter voltage across the resistance element forms the controller variable and the gate-source voltage or base-emitter voltage at the resistance element forms the manipulated variable, from which the measurement current or the value of the current through the resistance element is calculated directly or indirectly.

It is preferred for the drain-source voltage or collector-emitter voltage across the at least one transistor element, as the at least one resistance element, to be adjusted by at least one closed-loop control circuit to a constant value determined by a reference voltage source, independently of the current which flows through the resistance element. That is to say that the resistance element operates as a resistor controlled by closed-loop control.

Moreover, the invention also relates to the use of the current sensor in motor vehicles, in particular for measuring a discharge and/or charging current of an electrical energy store in an electric or hybrid vehicle.

### BRIEF DESCRIPTION OF THE FIGURES

Further preferred embodiments are evident from the dependent claims and the following descriptions of exemplary embodiments with reference to figures.

In the figures, in schematic illustration:

FIG. 1 shows an exemplary embodiment of the current sensor for measuring the charging and discharge current of a battery,

FIG. 2 shows an exemplary current sensor with two closed-loop control circuits, each comprising a resistance element, to which a senseFET is assigned,

FIG. 3 shows an exemplary illustration of the closed-loop control circuit of the current sensor, and

FIG. 4 shows an exemplary embodiment in which the resistance element comprises parallel-connected partial resistance elements which in this case can be switched in and out for extending the measurement range.

### DETAILED DESCRIPTION OF THE INVENTION

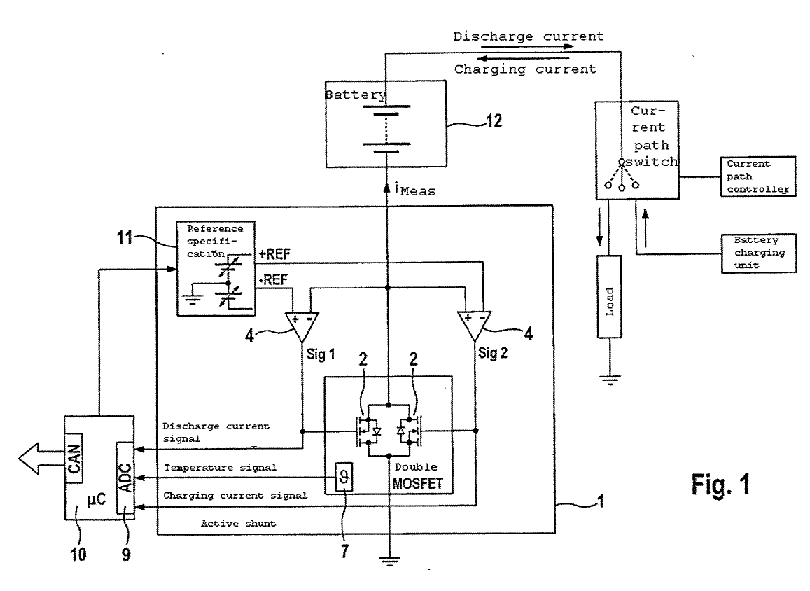

FIG. 1 shows an exemplary embodiment of the current sensor 1, which is used for measuring the discharge and charging current i_{Meas} of an electrical energy store or battery 12. In this case, current sensor 1 comprises a first and a second closed-loop control circuit, wherein the first closed-loop control circuit comprises the left resistance element 2, the left amplifier 4 or Sig1 and the reference voltage value specification of the reference voltage source 11 assigned thereto, and the second closed-loop control circuit comprises the right resistance element 2, the right amplifier 4 or Sig2 and the corresponding reference voltage value specification. The current i_{Meas} to be measured flows through the two resistance elements of the two closed-loop control circuits, wherein current flows through the resistance element of the first closed-loop control circuit during discharge and current flows through the resistance element of the second closed-loop control circuit during charging, that is to say when measurement current i_{Meas} has the opposite flow direction. The resistance elements 2 of the first and second closed-loop control circuits are designed, in accordance with the example, as two MOS field effect transistors designed complementarily to one another and are connected in parallel, wherein the drain terminal of one resistance element is respectively connected reciprocally to the source terminal of the other resistance element. In this case, the drain-source voltage of the two MOSFETS is adjusted to a defined reference voltage value, as a result of which the resistance value of the two resistance elements is fashioned in a manner substantially dependent on 1 divided by the value of the current i_{Meas} through the resistance element and the resistance value thus decreases as the measurement current i_{Meas} increases and the resistance value of the resistance element 2 increases as the current decreases. In order to measure the current, in this case the gate-source voltage of the corresponding resistance element is detected, which is the manipulated variable of the first and second closed-loop control circuits and is fed to the analog-to-digital converter 9. In addition, current sensor 1 has a temperature measuring element 7, which detects the temperature [symbol] of the two resistance elements 2, wherein this temperature is taken into account during the calculation of the measurement current in the signaling processing unit 10. The drain-source voltage to be controlled is in each case far less than the forward voltage of the parasitic diodes, with a value of a few mV. The temperature dependence of the transistor characteristic curves is taken into account by measurement of the transistor temperature and subsequent temperature compensation of the raw data.

The advantages here are, inter alia:
the voltages employed are considerably higher, for example more than 100 mV to a few volts, than at a shunt, voltages in the μV range, which results in a significantly higher EMC strength.
there is no need to use a special IC for picking up measured values, that is say that it is possible to use standard microcontrollers as the signal processing unit 10 with integrated AD converter 9, which keeps the costs low.

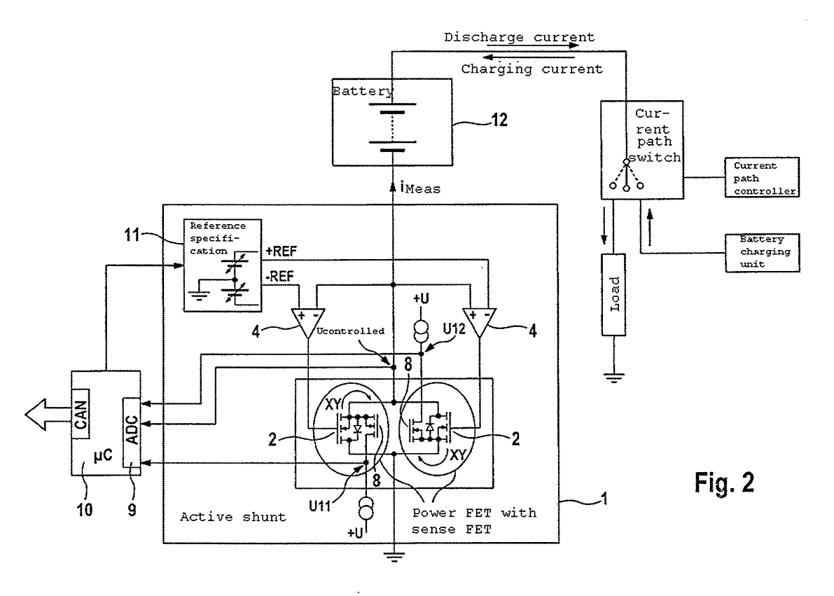

FIG. 2 illustrates an exemplary embodiment which, proceeding from the current sensor from FIG. 1, comprises a respective senseFET 8 assigned to the MosFET resistance elements of the two closed-loop control circuits. In other words, the two power FETs as resistance elements 2 are also respectively assigned a SENSEFET connected to analog-to-digital converter 9, wherein the current through the resistance element 2 is determined by means of the senseFET. The gate-source voltage of the senseFET is fashioned in each case to be identical to the gate-source voltage of the assigned resistance element or power FET. The quotient of the value of the drain-source resistance of the senseFET with respect to the value of the drain-source resistance of the assigned resistance element has a defined value X/Y. In this case, said value X/Y can be different for each path (X1/Y1-X2/Y2). The ratio of these two resistance values or value pairs is virtually temperature-independent and can be produced very accurately. A stable, precise current is applied to the two SENSEFETS by means of two separate current sources. If the voltages U11 and respectively U12 are then measured and divided by the known current of the current sources, this yields the adjusted resistance value of the power FETs divided by the division factor X/Y. Multiplication by the measured voltage Ucontrolled yields the current i_{Meas} flowing through the power FETS or resistance elements 2.

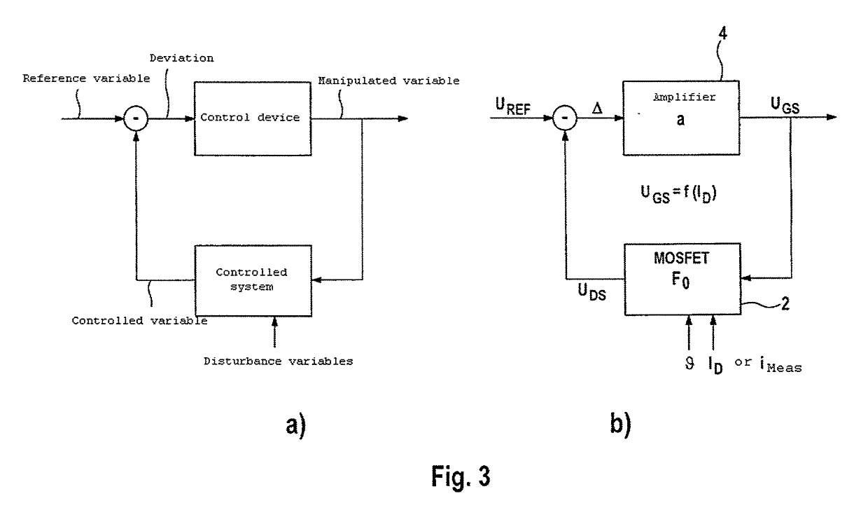

FIG. 3a) shows a schematic closed-loop control circuit, and an exemplary closed-loop control circuit of the current sensor is explained in comparison therewith with reference to FIG. 3b). The reference voltage value U_{REF} is the reference variable. In amplifier 4, designed as controller unit and actuating device, the manipulated variable U_{SS} is provided as a gate-source voltage, which is adjusted across the resistance element. The resistance element 2 itself forms the controlled system influenced by the measurement current i_{Meas} and the temperature [symbol] . Measurement current i_{Meas} is calculated from the controlled variable U_{DS} and drain-source voltage of the resistance element.

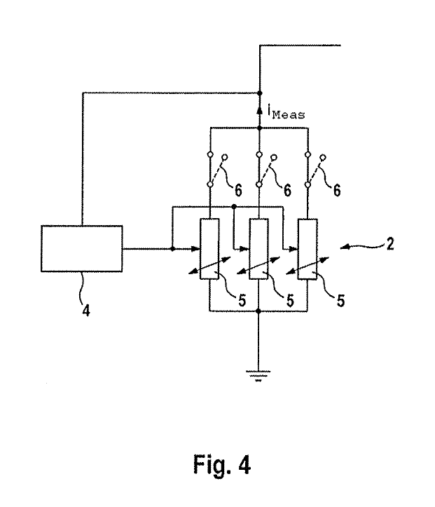

With reference to FIG. 4, an embodiment is illustrated in which resistance element 2 comprises three parallel-connected partial resistance elements 5, which are designed such that they can be switched in and out by switches 6, for extending the measurement range. The partial resistance elements 5 are driven by amplifier 4, as controller unit and actuating device.

### KEY TO THE FIGURES

1 Discharge current
2 Charging current
3 Battery
i_{Meas}
5 Current path
6 Current path controller
7 Battery charging unit
8 Load
9 Double
10 Discharge current signal
11 Temperature signal
12 Charging current signal
13 Active shunt
14 Reference specification
15 Ucontrolled
16 Power FET with sense FET
   [At bottom of page—REPLACEMENT SHEET (RULE 26)]
17 Reference variable
18 Deviation
19 Manipulated variable
20 Control device
21 Controlled system
22 Disturbance variables
23 Controller variable
24 Amplifier
25 I_{D} or I_{Meas}

1.-15. (canceled)

16. A current sensor, comprising at least one resistance element, to which a voltage (U_{GS}) for measuring the current (i_{Meas}) flowing through the resistance element is detected, wherein the resistance element is designed such that, at least within a defined measurement range of the current sensor, the electrical resistance of the resistance element decreases if the current (i_{Meas}) through the resistance element increases.

17. The current sensor as claimed in claim 16, wherein said current sensor is designed such that the percentage resolution of the current measurement relative to the present value of the current (i_{Meas}) through the resistance element remains substantially constant over the defined measurement range of the current sensor.

18. The current sensor as claimed in 16, wherein said current sensor comprises at least one closed-loop control circuit which is used to adjust the voltage (U_{DS}) across the resistance element to a defined reference voltage value, at least within a defined measurement range.

19. The current sensor as claimed in claim 18, wherein the defined reference voltage value is at least 1 mV.

20. The current sensor as claimed in claim 18, wherein said current sensor is designed such that the defined reference voltage is adjustable for extending the measurement range.

21. The current sensor as claimed in claim 16, wherein the resistance element comprises a transistor element, in particular a field effect transistor.

22. The current sensor as claimed in claim 21, wherein the voltage (U_{GS}) for measuring the current flowing through the resistance element is detected as gate-source voltage or base-emitter voltage at the transistor element.

23. The current sensor as claimed in claim 16, wherein the defined measurement range of the measurement current (i_{Meas}) comprises a measurement interval of at least four powers of ten, in particular at least five powers of ten.

24. The current sensor as claimed in claim 18, wherein with voltage (U_{DS}) across the resistance element controlled by closed-loop control, the resistance value of the resistance element is substantially dependent on 1 divided by the value of the current (i_{Meas}) through the resistance element or is substantially dependent on 1 divided by the root of the value of the current (i_{Meas}) through the resistance element.

25. The current sensor as claimed in claim 16, wherein the at least one resistance element comprises two or more parallel-connected partial resistance elements which are designed such that they can be switched in and/or out, substantially for extending the measurement range.

26. The current sensor as claimed in claim 16, wherein said current sensor has at least one temperature measuring element which detects the temperature ( [symbol] ) of the at least one resistance element, wherein said temperature is taken into account during the measurement of the current (i_{Meas}) flowing through the at least one resistance element, in particular by a calculation in at least one signal processing unit of the current sensor.

27. The current sensor as claimed in claim 18, wherein said current sensor comprises a first and a second closed-loop control circuit, which are used in each case to adjust the voltage (U_{DS}) across a resistance element to a defined reference voltage value, at least within a defined measurement range, wherein the current to be measured can flow with a first defined direction through the resistance element of the first closed-loop control circuit and the current to be measured can flow with a second direction, opposite to the first direction, through the resistance element of the second closed-loop control circuit, and the current to be measured is detected and measured by means of the first closed-loop control circuit or by means of the second closed-loop control circuit, depending on the current direction.

28. The current sensor as claimed in claim 27, wherein the resistance elements of the first and second closed-loop control circuits are designed as two field effect transistors designed complementarily to one another, and/or in that the resistance elements of the first and second closed-loop control circuits are connected in parallel and in this case the drain terminal or collector terminal of one resistance element is respectively connected to the source terminal or emitter terminal of the other resistance element, in particular reciprocally.

29. The current sensor as claimed in claim 16, wherein the at least one resistance element is assigned at least one senseFET connected to an analog-to-digital converter, wherein the current (i_{Meas}) through the resistance element is determined by means of the senseFET.

30. The use of the current sensor as claimed in claim 16 in emitter vehicles, for measuring a discharge and/or charging current of an electrical energy store in an electric or hybrid vehicle.
